(19) United States
(12) Patent Application Publication
(10) Pub. No.: US 2026/0079225 A1
(43) Pub. Date: Mar. 19, 2026

(54) DETECTION APPARATUS, ENERGY STORAGE APPARATUS, AND DETECTION METHOD

(71) Applicant: GS Yuasa International Ltd., Kyoto-shi, Kyoto (JP)

(72) Inventor: Mitsushi MUKAIDA, Kyoto-shi, Kyoto (JP)

(21) Appl. No.: 19/103,423

(22) PCT Filed: Aug. 4, 2023
(86) PCT No.: PCT/JP2023/028590

§ 371 Date: Feb. 12, 2025

(30) Foreign Application Priority Data
Aug. 25, 2022 (JP) 2022-133941

(51) Int. Cl. G01R 35/00; B60L 3/00; G01R 31/382; H01M 10/42; H01M 50/249

(52) U.S. Cl. CPC G01R 35/00; B60L 3/0046; G01R 31/382; H01M 10/425; H01M 50/249; B60L 2240/549; H01M 2010/4271; H01M 2220/20

(57) ABSTRACT

A detection apparatus (a current detection circuit and a control unit) which detects a measurement characteristic of a current measurement circuit which measures a current value of a current that flows through a circuit, the detection apparatus including: the current detection circuit which detects, for a plurality of reference current values different from each other, a flow of the reference current value having occurred in the circuit; and the control unit, in which the control unit measures, when the flow of the reference current value is detected to have occurred, a plurality of current values by the current measurement circuit, and detects the measurement characteristic of the current measurement circuit on the basis of the plurality of reference current values and the plurality of current values measured by the current measurement circuit.

### CROSS REFERENCE TO RELATED APPLICATIONS

This application is a National Stage Application, filed under 35 U.S.C. § 371, of International Application No. PCT/JP2023/028590, filed Aug. 4, 2023, which international application claims priority to and the benefit of Japanese Application No. 2022-133941, filed Aug. 25, 2022; the contents of both of which are hereby incorporated by reference in their entirety.

### BACKGROUND

### Technical Field

The technology disclosed in the present specification relates to a detection apparatus, an energy storage apparatus, and a detection method for detecting a measurement characteristic of a current measurement circuit which measures a current value of a current that flows through a circuit.

### Description of Related Art

Conventionally, detecting a measurement characteristic of a current measurement circuit, which measures a current value of a current that flows through a circuit, has been conducted (for example, see Japanese Application Publication 2007-192723 (“JP2007-192723 A”) and Japanese Application Publication 2011-151986 (“JP2011-151986 A”).

A current sensor correction system described in JP2007-192723 A is provided with a current measurement circuit 4 which is connected to a current path connecting a battery 1 and an electric load 3, and a selector switch 7 which is connected in series with the current measurement circuit 4. In the current sensor correction system, when the selector switch 7 is connected to contact A, electric power is supplied from the battery 1 to the electric load 3, and when the selector switch 7 is switched to contact B, the electric power is prevented from being supplied to the electric load 3. The current sensor correction system detects an offset error and a gain error of the current measurement circuit 4 in a state in which the selector switch 7 is switched to contact B (that is, a state in which no electric power is supplied to the electric load 3).

An abnormality diagnosis apparatus for a current sensor described in JP2011-151986 A is provided with two current sensors, i.e., a current sensor 30a and a current sensor 30b, which are connected in series. The abnormality diagnosis apparatus detects an offset error and a gain error of the two current sensors on the basis of detection values detected at the same timing by the two current sensors 30a and 30b.

### BRIEF SUMMARY

The current sensor correction system described in JP2007-192723 A and the abnormality diagnosis apparatus for a current sensor described in JP2011-151986 A above leave room for improvement in detecting the measurement characteristic of the current measurement circuit. An object of one aspect of the present invention is to detect a measurement characteristic of a current measurement circuit while an electric load is being supplied with electric power, and without providing another current measurement circuit.

A detection apparatus which detects a measurement characteristic of a current measurement circuit which measures a current value of a current that flows through a circuit, the detection apparatus including: a current detection circuit which detects, for a plurality of reference current values different from each other, a flow of the reference current value having occurred in the circuit; and a control unit, in which the control unit measures, when the flow of the reference current value is detected to have occurred, a plurality of current values by the current measurement circuit, and detects the measurement characteristic of the current measurement circuit on the basis of the plurality of reference current values and the plurality of current values measured by the current measurement circuit.

According to the above configuration, it is possible to detect the measurement characteristic of the current measurement circuit while an electric load is being supplied with electric power, and without providing another current measurement circuit.

### BRIEF DESCRIPTION OF THE FIGURES

FIG. 1 is a schematic diagram of a vehicle and an energy storage apparatus according to Embodiment 1.

FIG. 2 is an exploded perspective view of the energy storage apparatus.

FIG. 3A is a plan view of an energy storage cell.

FIG. 3B is a cross-sectional view taken along line A-A indicated in FIG. 3A.

FIG. 4 is a block diagram illustrating an electrical configuration of the energy storage apparatus.

FIG. 5 is a graph showing a change in an output signal of a current detection circuit.

FIG. 6 is a graph in which the X-axis represents a reference current value and the Y-axis represents a current value measured by a current measurement circuit (case where there is no abnormality in the current measurement circuit).

FIG. 7 is a flowchart of abnormality detection processing for a current measurement circuit and correction formula setting processing for the current measurement circuit.

FIG. 8 is a flowchart (former part) of abnormality detection processing for a current measurement circuit and correction formula setting processing for the current measurement circuit according to Embodiment 2.

FIG. 9 is a flowchart (latter part) of the abnormality detection processing for the current measurement circuit and the correction formula setting processing for the current measurement circuit according to Embodiment 2.

### DETAILED DESCRIPTION OF VARIOUS EMBODIMENTS

### Outline of Embodiment

(1) A detection apparatus according to an embodiment pertains to a detection apparatus which detects a measurement characteristic of a current measurement circuit which measures a current value of a current that flows through a circuit, and the detection apparatus is provided with: a current detection circuit which detects, for a plurality of reference current values different from each other, a flow of the reference current value having occurred in the circuit; and a control unit, in which the control unit measures, when the flow of the reference current value is detected to have occurred, a plurality of current values by the current measurement circuit, and detects the measurement characteristic of the current measurement circuit on the basis of the plurality of reference current values and the plurality of current values measured by the current measurement circuit.

When electric power is to be supplied to an electric load, it may be required that the electric power supply to the electric load be maintained as much as possible. In the case where the measurement characteristic of a current measurement circuit, which measures a current that flows through a circuit for supplying electric power to the electric load as described above, is to be detected, it is not possible to perform the detection in a state in which no electric power is supplied to the electric load by switching the selector switch as in the current sensor correction system described in JP2007-192723 A.

In the detection apparatus according to (1) described above, when the measurement characteristic of the current measurement circuit is to be detected, there is no need to switch the circuit by the selector switch so that no electric power is supplied to the electric load. Therefore, it is possible to detect the measurement characteristic of the current measurement circuit while the electric load is being supplied with electric power.

In the detection apparatus according to (1) described above, the measurement characteristic of the current measurement circuit is detected by using the current detection circuit. Thus, there is no need to provide a plurality of current measurement circuits as in the abnormality diagnosis apparatus for a current sensor described in JP2011-151986 A.

Therefore, according to the detection apparatus described in (1) above, it is possible to detect the measurement characteristic of the current measurement circuit while the electric load is being supplied with electric power, and without providing another current measurement circuit.
(2) In the detection apparatus according to (1) described above, the control unit may measure the current value by the current measurement circuit immediately when the flow of the reference current value is detected to have occurred.

According to the detection apparatus described in (2) above, a current value is measured by the current measurement circuit immediately when a flow of a reference current value is detected to have occurred. Thus, a time difference between the time when the flow of the reference current value is detected to have occurred and the time when the current value is measured by the current measurement circuit can be made as small as possible. Consequently, it is possible to detect the measurement characteristic of the current measurement circuit more accurately than in the case where the time difference is large.
(3) In the detection apparatus according to (1) or (2) described above, the measurement characteristic is an offset error, and the control unit may detect, in a coordinate system in which one axis represents the reference current value and the other axis represents the current value measured by the current measurement circuit, an intercept of a line passing through the current value measured by the current measurement circuit in response to detecting that a flow of a first reference current value, which is one of the plurality of reference current values, has occurred, and the current value measured by the current measurement circuit in response to detecting that a flow of a second reference current value, which is one of the plurality of reference current values, has occurred as the offset error.

In the detection apparatus according to (3) described above, when the offset error of the current measurement circuit is to be detected, there is no need to switch the circuit by the selector switch so that no electric power is supplied to the electric load. Therefore, it is possible to detect the offset error of the current measurement circuit while the electric load is being supplied with electric power.

In the detection apparatus according to (3) described above, the offset error of the current measurement circuit is detected by using the current detection circuit. Thus, there is also no need to provide a plurality of current measurement circuits as in the abnormality diagnosis apparatus for a current sensor described in JP2011-151986 A.

Therefore, according to the detection apparatus described in (3) above, it is possible to detect the offset error of the current measurement circuit while the electric load is being supplied with electric power, and without providing another current measurement circuit.

The “coordinate system” described above can also be rephrased as “correlation data”, “relative value”, or “comparative value”. The same applies to the “coordinate system” which will be described hereafter.
(4) In the detection apparatus according to (3) described above, the line may be a straight line.

Since the straight line can be specified by two points on a coordinate system, the number of times the current value is measured for detecting the offset error can be reduced relative to a curved line.
(5) In the detection apparatus according to any one of (1) to (4) described above, the measurement characteristic is a gain error, and the control unit may detect, in a coordinate system in which one axis represents the reference current value and the other axis represents the current value measured by the current measurement circuit, a slope of a line passing through the current value measured by the current measurement circuit in response to detecting that a flow of a first reference current value, which is one of the plurality of reference current values, has occurred, and the current value measured by the current measurement circuit in response to detecting that a flow of a second reference current value, which is one of the plurality of reference current values, has occurred as the gain error.

In the detection apparatus according to (5) described above, when the gain error of the current measurement circuit is to be detected, there is no need to switch the circuit by the selector switch so that no electric power is supplied to the electric load. Therefore, it is possible to detect the gain error of the current measurement circuit while the electric load is being supplied with electric power.

In the detection apparatus according to (5) described above, the gain error of the current measurement circuit is detected by using the current detection circuit. Thus, there is also no need to provide a plurality of current measurement circuits as in the abnormality diagnosis apparatus for a current sensor described in JP2011-151986 A.

Therefore, according to the detection apparatus described in (5) above, it is possible to detect the gain error of the current measurement circuit while the electric load is being supplied with electric power, and without providing another current measurement circuit.
(6) In the detection apparatus according to (5) described above, the line may be a straight line. Since the straight line can be specified by two points on a coordinate system, the number of times the current value is measured for detecting the gain error can be reduced relative to a curved line.
(7) In the detection apparatus according to any one of (1) to (6) described above, the control unit may detect the presence or absence of abnormality in the current measurement circuit by comparing the detected measurement characteristic with a threshold value.

When the measurement characteristic of the current measurement circuit is greatly changed from the intrinsic measurement characteristic, the measurement accuracy of the current measurement circuit is lowered, so that it becomes impossible to accurately measure the current value. It can be said that an abnormality is caused in a current measurement circuit not capable of accurately detecting a current value.

According to the detection apparatus described in (7) above, since the detected measurement characteristic is compared with a threshold value, it is possible to detect the presence or absence of abnormality in the current measurement circuit.
(8) In the detection apparatus according to (7) described above, the current detection circuit has a function of self-diagnosing the presence or absence of abnormality in the current detection circuit itself, and the control unit may determine that the current measurement circuit is abnormal in a case where a result of comparing the detected measurement characteristic with the threshold value indicates abnormality and a result of self-diagnosis of the current measurement circuit also indicates abnormality.

According to the detection apparatus described in (8) above, abnormality of the current measurement circuit is detected by two methods, and if abnormality is indicated by both of the two methods, the current measurement circuit is determined as being abnormal. Therefore, it is possible to reduce the possibility of erroneously judging that the current measurement circuit is abnormal despite not being abnormal.
(9) In the detection apparatus according to (7) or (8) described above, if no abnormality is detected in the current measurement circuit, the control unit may set a correction formula for correcting the current value measured by the current measurement circuit on the basis of the detected measurement characteristic.

Even if no abnormality is detected in the current measurement circuit, the measurement characteristic may be changed from the intrinsic measurement characteristic within a normal range. When the measurement characteristic of the current measurement circuit is changed from the intrinsic measurement characteristic, the measurement accuracy of the current measurement circuit is lowered in accordance with the change.

According to the detection apparatus described in (9) above, if no abnormality is detected in the current measurement circuit, a correction formula is set on the basis of the measurement characteristic. Therefore, by correcting the current value which has been measured by the current measurement circuit by using the correction formula, it is possible to obtain a highly accurate current value even if a change occurs in the measurement characteristic of the current measurement circuit.

The reason why the correction formula is not set when an abnormality of the current measurement circuit is detected is that there may be a case where continuously using the current measurement circuit is not desirable if the abnormality is detected.
(10) In the detection apparatus according to any one of (1) to (9) described above, a storage unit is provided and the control unit stores, in the storage unit, the current value measured by the current measurement circuit in response to detecting that a flow of the reference current value has occurred, and if the number of stored current values reaches a predetermined number or more, the control unit may compare a current value, which is thereafter measured by the current measurement circuit in response to detecting that a flow of the reference current value has occurred, with a plurality of current values stored in the storage unit, thereby determining whether the measurement characteristic of the current measurement circuit has been changed, and detect, when it is determined that the measurement characteristic has been changed, the measurement characteristic.

Normally, a change of the measurement characteristic of the current measurement circuit does not occur frequently. Therefore, if the measurement characteristic is detected every time a flow is detected to have occurred for a plurality of reference current values, it is possible that the detection of the measurement characteristic may be conducted excessively.

According to the detection apparatus described in (10) above, a measurement characteristic is detected when it is determined that the measurement characteristic of the current measurement circuit has been changed. Thus, it is possible to suppress excessive detection of the measurement characteristic as compared to the case of detecting the measurement characteristic each time a flow is detected to have occurred for a plurality of reference current values.

Here, when the measurement characteristic of the current measurement circuit is changed, a difference between the current value measured by the current measurement circuit in response to detecting that the flow of the reference current value has occurred and the plurality of current values stored in the storage unit is increased. Therefore, by comparing the current value measured by the current measurement circuit in response to detecting that the flow of the reference current value has occurred with the plurality of current values that are stored in the storage unit, it is possible to determine whether or not the measurement characteristic of the current measurement circuit has been changed.
(11) In the detection apparatus according to any one of (1) to (10) described above, the detection accuracy of the current detection circuit may be equal to or higher than the measurement accuracy of the current measurement circuit.

In the detection apparatus according to (11) described above, when a flow of the reference current value is detected to have occurred, the current value is measured by the current measurement circuit. However, if the detection accuracy of the current detection circuit is low, even if the current detection circuit detects that a flow of the reference current value has occurred, actually, it is the case that there is no flow of the reference current value at that time. In this case, if the measurement characteristic is detected on the basis of the reference current value and the current value measured by the current measurement circuit, the current value measured by the current measurement circuit is not actually the current value to be obtained when a flow of the reference current value has occurred. Therefore, the accuracy of detecting the measurement characteristic is lowered. Therefore, in order to detect the measurement characteristic of the current measurement circuit with high accuracy, it is preferable that the detection characteristic of the current detection circuit should be high to some extent.

According to the detection apparatus described in (11) above, the detection accuracy of the current detection circuit is equal to or higher than the measurement accuracy of the current measurement circuit. Thus, it is possible to detect the measurement characteristic of the current measurement circuit more accurately than in the case where the detection accuracy of the current detection circuit is less than the measurement accuracy of the current measurement circuit.
(12) An energy storage apparatus according to the embodiment is provided with: an energy storage cell; a current measurement circuit which measures a current value of a current that flows through a circuit to which the energy storage cell is connected; and the detection apparatus according to any one of (1) to (11) described above.

According to the energy storage apparatus described in (12) above, it is possible to detect the measurement characteristic of the current measurement circuit while the electric load is being supplied with electric power, and without providing another current measurement circuit.
(13) In the energy storage apparatus according to (12) described above, the energy storage apparatus may be mounted on a vehicle having a load that needs to be supplied with electric power.

The vehicle having a load that needs to be supplied with electric power may be required to maintain the electric power supply to the electric load as much as possible.

According to the energy storage apparatus described in (13) above, since the measurement characteristic of the current measurement circuit can be detected while an electric load is being supplied with electric power, the energy storage apparatus is suitable for a vehicle having a load that needs to be supplied with electric power.

### DETAILS OF EMBODIMENT

Embodiments of the present disclosure will be described below. The present disclosure is not limited to these examples illustrated, but is defined by the scope of the claims and is intended to include all modifications within the meaning and scope equivalent to the scope of the claims. The embodiments of the present disclosure may be realized in various aspects, e.g., an apparatus, a method, a computer program for realizing the functions of the apparatus or the method, and a recording medium in which the computer program is recorded.

### Embodiment 1

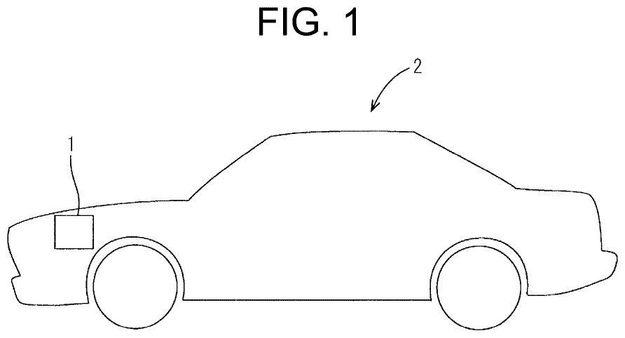

Embodiment 1 will be described with reference to FIGS. 1 to 7. In the following description, indication of reference numerals of the drawings may be omitted for the same constituent elements except for some cases.

### (1) Energy Storage Apparatus

An energy storage apparatus 1 according to Embodiment 1 will be described with reference to FIG. 1. The energy storage apparatus 1 is mounted on a vehicle 2 such as an automobile, and supplies electric power to an engine starting device (a starter motor) and auxiliary machines (a vehicle engine control unit (ECU), power steering, a brake, a headlight, an air-conditioner, a car navigation system, and the like) that are provided in the vehicle 2. The energy storage apparatus 1 is charged by a vehicle generator (an alternator). The energy storage apparatus 1 may be charged by regenerative charging under braking.

The auxiliary machines are an example of an electric load and a load that needs to be supplied with electric power. Normally, it is required that the energy storage apparatus 1 which is mounted on the vehicle 2 maintain the electric power supply to the auxiliary machines while the vehicle 2 is traveling. The vehicle 2 is an example of a vehicle having a load that needs to be supplied with electric power.

### (2) Configuration of Energy Storage Apparatus

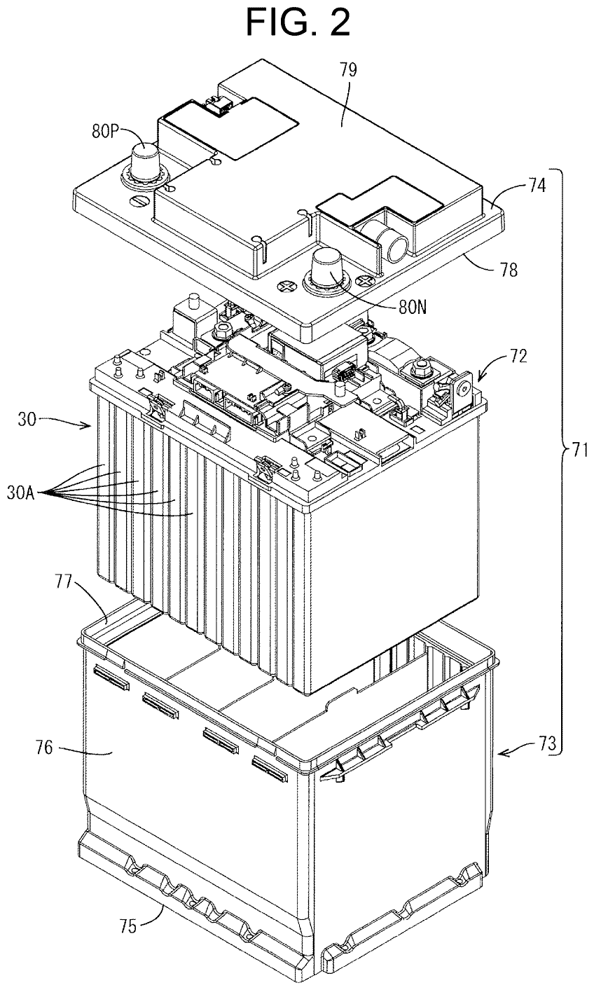

As illustrated in FIG. 2, the energy storage apparatus 1 includes a housing body 71. The housing body 71 includes a main body 73 and a lid body 74 which are made of a synthetic resin material. The main body 73 has a bottom-closed cylindrical shape. The main body 73 is provided with a bottom surface portion 75 and four side surface portions 76. An upper opening portion 77 is formed at an upper end part by the four side surface portions 76.

The housing body 71 houses therein an assembled battery 30 constituted of a plurality of energy storage cells 30A, and a circuit board unit 72. The energy storage cell 30A is a repeatedly chargeable and dischargeable secondary battery, and to be more specific, is a lithium-ion secondary battery, for example. The circuit board unit 72 is disposed on the upper part of the assembled battery 30.

The lid body 74 closes the upper opening portion 77 of the main body 73. An outer peripheral wall 78 is provided around the lid body 74. The lid body 74 includes a protruding portion 79 which is substantially T-shaped in plan view. A positive electrode external terminal 80P is fixed to one corner portion of the front part of the lid body 74, and a negative electrode external terminal 80N is fixed to the other corner portion.

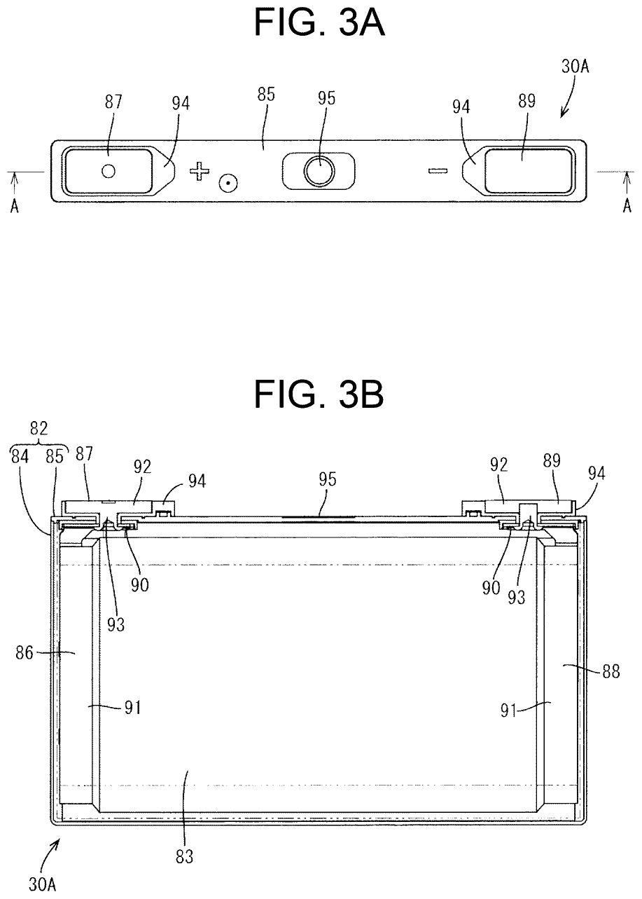

As illustrated in FIGS. 3A and 3B, the energy storage cell 30A is obtained by accommodating an electrode body 83, together with a non-aqueous electrolyte, in a case 82 having a rectangular parallelepiped shape. The case 82 includes a case main body 84 and a lid 85, which closes an opening portion above the case main body 84.

Although not illustrated in detail, the electrode body 83 is obtained by arranging a separator made of a porous resin film between a negative electrode element having a negative electrode active material applied to a base material that is made of copper foil and a positive electrode element having a positive electrode active material applied to a base material that is made of aluminum foil. The above components are all band-shaped, and are wound in a flat shape such that they can be accommodated in the case main body 84 in such a state that the negative electrode element and the positive electrode element are positionally shifted to the opposite sides in a width direction with respect to the separator.

A positive electrode terminal 87 is connected to the positive electrode element via a positive electrode current collector 86, and a negative electrode terminal 89 is connected to the negative electrode element via a negative electrode current collector 88. The positive electrode current collector 86 and the negative electrode current collector 88 are each composed of a pedestal portion 90 having a flat plate shape, and a leg portion 91 extending from the pedestal portion 90. A through hole is formed in the pedestal portion 90. The leg portion 91 is connected to the positive electrode element or the negative electrode element. The positive electrode terminal 87 and the negative electrode terminal 89 are each composed of a terminal main body portion 92 and a shaft portion 93 protruding downward from a central part of a lower surface of the terminal main body portion 92. Of the above, the terminal main body portion 92 and the shaft portion 93 of the positive electrode terminal 87 are integrally formed of aluminum (a single material). In the negative electrode terminal 89, the terminal main body portion 92 is made of aluminum and the shaft portion 93 is made of copper, and they are assembled to the negative electrode terminal 89. The terminal main body portions 92 of the positive electrode terminal 87 and the negative electrode terminal 89 are disposed at both end portions of the lid 85 via gaskets 94 made of an insulating material, and are exposed to the outside from the gaskets 94.

As illustrated in FIG. 3A, the lid 85 includes a pressure release valve 95. The pressure release valve 95 is located between the positive electrode terminal 87 and the negative electrode terminal 89. When the internal pressure of the case 82 exceeds a limit value, the pressure release valve 95 is opened to lower the internal pressure of the case 82.

### (3) Electrical Configuration of Energy Storage Apparatus

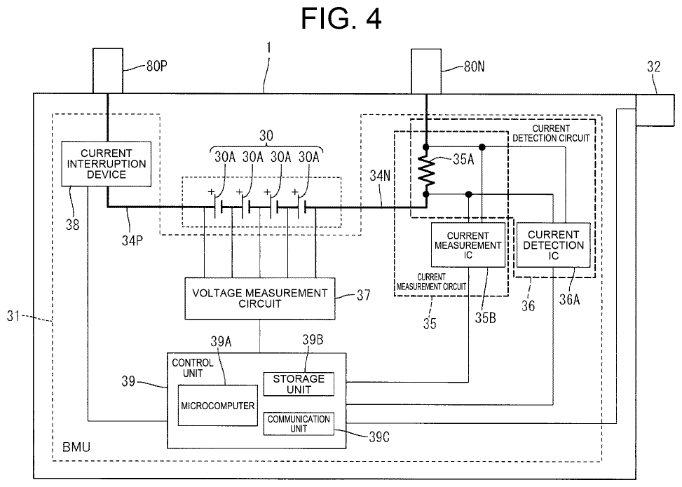

As illustrated in FIG. 4, the energy storage apparatus 1 is provided with the assembled battery 30, a battery management unit (BMU) 31, and a communication connector 32.

The assembled battery 30 is connected to the positive electrode external terminal 80P by a power line 34P, and is connected to the negative electrode external terminal 80N by a power line 34N. In the assembled battery 30, twelve energy storage cells 30A are connected to establish a three-parallel and four-series connection. In FIG. 4, three energy storage cells 30A connected in parallel are represented by one battery symbol. A current path from the negative electrode external terminal 80N to the positive electrode external terminal 80P is an example of a circuit.

The BMU 31 is a device which manages the energy storage apparatus 1. The BMU 31 is provided with a current measurement circuit 35, a current detection circuit 36, a voltage measurement circuit 37, a current interruption device 38, and a control unit 39. The BMU 31 is operated by electric power supplied from the energy storage cells 30A. The current detection circuit 36 and the control unit 39 constitute a detection apparatus according to Embodiment 1.

The current measurement circuit 35 is a circuit which measures a current value of a charge/discharge current that flows through the circuit to which the energy storage cells 30A are connected. The current measurement circuit 35 includes a shunt resistor 35A provided in the power line 34N, and a current measurement integrated circuit (IC) 35B which is connected in parallel with the shunt resistor 35A. The current measurement IC 35B measures the current value on the basis of a resistance value of the shunt resistor 35A, an internal resistance value of the current measurement IC 35B, and a current value of a current that flows through the current measurement IC 35B.

The current detection circuit 36 is a circuit which detects a flow of a reference current value of +10 A (an example of a first reference current value) having occurred (i.e., in other words, detects the time when a flow of the reference current value has occurred) through the power line 34N, and a flow of a reference current value of −10 A (an example of a second reference current value) having occurred (i.e., in other words, detects the time when a flow of the reference current value has occurred) through the power line 34N. The current detection circuit 36 includes the shunt resistor 35A, and a current detection IC 36A which is connected in parallel with the shunt resistor 35A. The shunt resistor 35A is shared with the current measurement circuit 35. The current detection IC 36A will be described later.

The voltage measurement circuit 37 is connected to each of both ends of each energy storage cell 30A by a signal line. The voltage measurement circuit 37 measures the battery voltage [V] of each of the energy storage cells 30A and outputs the measured battery voltage to the control unit 39. A total voltage [V] of the assembled battery 30 is a summed voltage of the four energy storage cells 30A connected in series.

The current interruption device 38 is provided in the power line 34P. The current interruption device 38 is opened by the control unit 39 when an abnormality of the energy storage apparatus 1 is detected (or when an abnormality is predicted). As the current interruption device 38, a latch-type relay, a field-effect transistor (FET), etc., can be used.

The control unit 39 is provided with a microcomputer 39A including a CPU and a RAM, etc., as one chip, a storage unit 39B, and a communication unit 39C. The microcomputer 39A manages each unit of the energy storage apparatus 1 by executing a management program stored in the storage unit 39B. The storage unit 39B includes a non-volatile storage medium which can be repeatedly rewritten. The storage unit 39B stores therein the management program to be executed by the control unit 39 and various kinds of data. As will be described in detail later, current values measured by the current measurement circuit 35, and the like, are also stored in the storage unit 39B.

The communication unit 39C is a circuit for enabling the BMU 31 to communicate with the vehicle ECU. The communication connector 32 is a connector to which a communication cable for use by the BMU 31 to communicate with the vehicle ECU is connected.

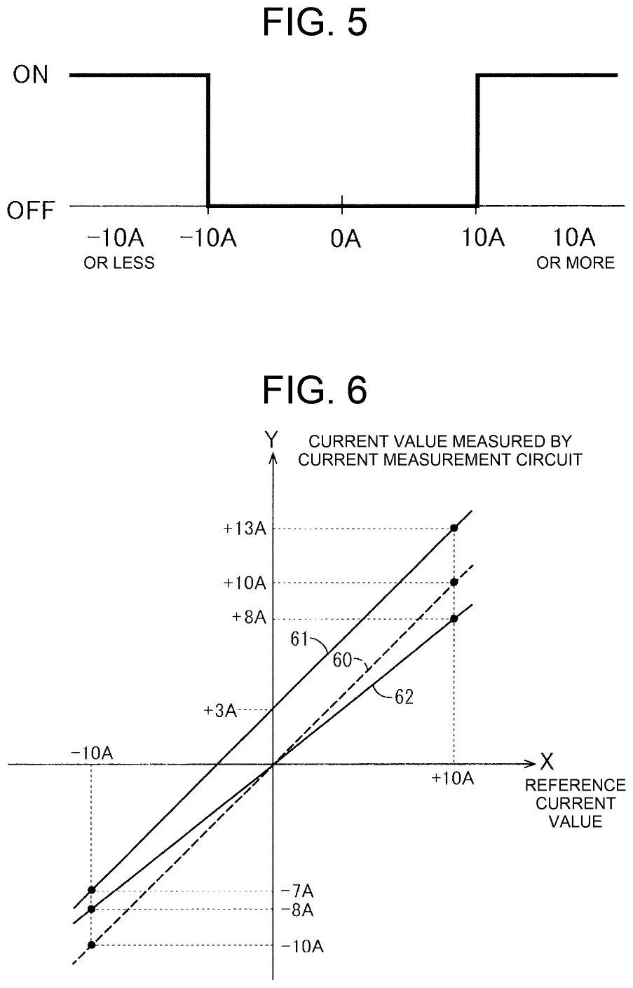

The current detection IC 36A will be described with reference to FIG. 5. The current detection IC 36A includes two comparators. The comparator is a logic circuit which compares an input signal (a voltage in this case) with a reference signal and outputs an OFF signal when the input signal is less than the reference signal, and outputs an ON signal when the input signal is greater than or equal to the reference signal. In one comparator, a voltage value to be exhibited when a current of +10 A flows through the shunt resistor 35A is set as the reference signal. In the other comparator, a voltage value to be exhibited when a current of −10 A flows through the shunt resistor 35A is set as the reference signal. A current value may be set to the current detection IC 36A as the reference signal.

When an engine of the vehicle 2 is to be started, a current value of a discharge current that flows from the energy storage apparatus 1 to the engine starting device changes from less than +10 A to +10 A or more. Therefore, when the engine is started, an output signal of the one comparator changes from OFF to ON. Conversely, when the current value changes from +10 A or more to less than +10 A, an output signal of the above-mentioned one comparator changes from ON to OFF.

The control unit 39 detects a flow of the current value of +10 A having occurred by detecting that the output signal of the one comparator has changed from OFF to ON. Similarly, the control unit 39 detects a flow of the current value of +10 A having occurred by detecting that the output signal has changed from ON to OFF. The control unit 39 may detect only one of a change made from OFF to ON and a change made from ON to OFF.

When the energy storage apparatus 1 is to be charged by the vehicle generator, a current value of a charge current that flows from the vehicle generator to the energy storage apparatus 1 changes from a value greater than −10 A (less than 10 A in the absolute value) to −10 A or less (10 A or more in the absolute value). Therefore, when the energy storage apparatus 1 is charged, an output signal of the other comparator changes from OFF to ON. Conversely, when the current value changes from a value less than or equal to −10 A to a value greater than −10 A, an output signal of the above-mentioned other comparator changes from ON to OFF.

The control unit 39 detects a flow of the current value of −10 A having occurred by detecting that the output signal of the other comparator has changed from OFF to ON. Similarly, the control unit 39 detects a flow of the current value of −10 A having occurred by detecting that the output signal has changed from ON to OFF. The control unit 39 may detect only one of a change made from OFF to ON and a change made from ON to OFF.

The detection accuracy of the current detection circuit 36 is equal to or higher than the measurement accuracy of the current measurement circuit 35. The detection accuracy of the current detection circuit 36 being equal to or higher than the measurement accuracy of the current measurement circuit 35 means that a difference between the value of a current actually flowing at the time when the current detection circuit 36 has detected that a flow of the reference current value has occurred and the reference current value is equal to or smaller than the current value measured by the current measurement circuit 35 at the time when a flow of the reference current value is detected to have occurred and the value of a current actually flowing.

### (4) Processing Executed by Control Unit

SOC estimation processing, operation mode switching processing, abnormality detection processing for the current measurement circuit, and correction formula setting processing for the current measurement circuit to be executed by the control unit 39 will be described.

### (4-1) SOC Estimation Processing

The SOC estimation processing is the processing of estimating the state of charge (SOC) of the energy storage apparatus 1 by using the current measurement circuit 35. The control unit 39 measures the charge/discharge current of the energy storage apparatus 1 at predetermined time intervals by the current measurement circuit 35, and estimates the SOC by adding or subtracting the measured current value to or from the initial value. When the SOC increases to a predetermined upper limit value, the control unit 39 opens the current interruption device 38 in order to protect the energy storage cells 30A from an overcharge. When the SOC decreases to a predetermined lower limit value, the control unit 39 opens the current interruption device 38 in order to protect the energy storage cells 30A from an overdischarge.

### (4-2) Operation Mode Switching Processing

The operation mode switching processing is the processing of switching the operation mode of the BMU 31 in order to suppress power consumption of the BMU 31. When the vehicle 2 is traveling (in other words, when the engine is being operated), the energy storage apparatus 1 is charged by the vehicle generator. Thus, the control unit 39 operates the BMU 31 in a normal mode. When the vehicle 2 is being parked (in other words, when the engine is being stopped), the energy storage apparatus 1 is not charged. Thus, the control unit 39 switches the BMU 31 to be in a low power consumption mode (hereinafter referred to as a sleep mode) in which the power consumption is lower than that of the normal mode in order to suppress the power consumption of the BMU 31. In the sleep mode, an operation clock of the BMU 31 is lower than that of the normal mode.

When a discharge current flows from the energy storage apparatus 1 to the engine starting device in the sleep mode, an output signal of the current detection circuit 36 changes from OFF to ON. Also when an external charging device is connected to the energy storage apparatus 1 in the sleep mode, an output signal of the current detection circuit 36 changes from OFF to ON. When the output signal of the current detection circuit 36 changes from OFF to ON, the control unit 39 causes the BMU 31 to return to the normal mode (in other words, wakes up the BMU 31). That is, the current detection circuit 36 is also used for the switching of the operation mode of the BMU 31.

### (4-3) Abnormality Detection Processing for Current Measurement Circuit

The abnormality detection processing for the current measurement circuit is the processing of detecting a measurement characteristic of the current measurement circuit 35 by using the current detection circuit 36, and detecting the presence or absence of abnormality in the current measurement circuit 35 by comparing the detected measurement characteristic with a threshold value. In the following description, an offset abnormality and a gain abnormality will be described as examples of the abnormality of the current measurement circuit 35.

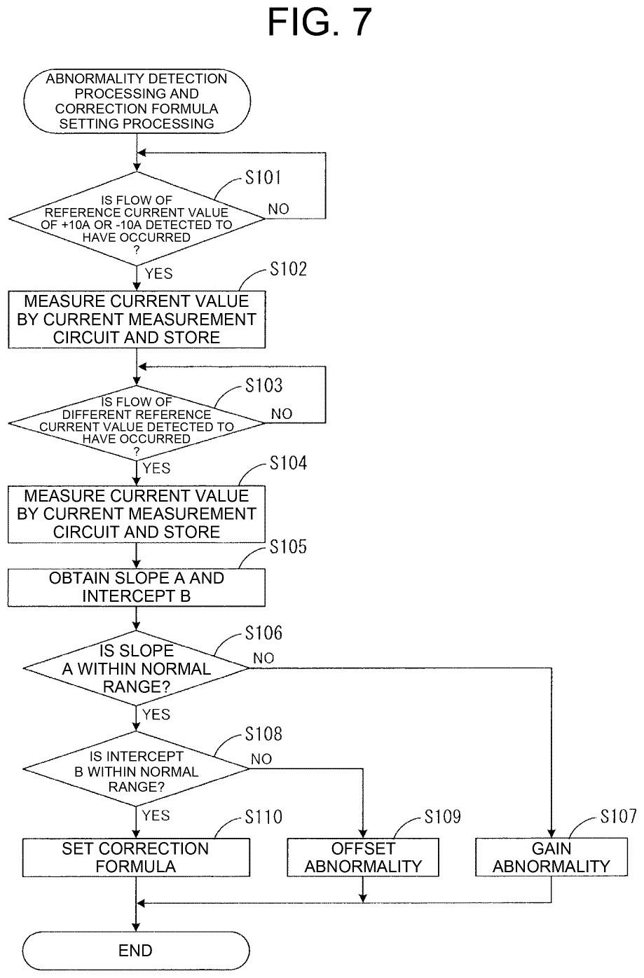

The X-axis of a coordinate system illustrated in FIG. 6 represents a reference current value, and the Y-axis of the same represents a current value measured by the current measurement circuit 35. When the current detection IC 36A detects that a flow of the reference current value of +10 A has occurred, the control unit 39 immediately measures the current value by the current measurement circuit 35. Similarly, when the current detection IC 36A detects that a flow of the reference current value of −10 A has occurred, the control unit 39 immediately measures the current value by the current measurement circuit 35.

The control unit 39 detects a slope A of a straight line passing through the current value measured by the current measurement circuit 35 in response to detecting that the flow of the reference current value of +10 A has occurred and the current value measured by the current measurement circuit 35 in response to detecting that the flow of the reference current value of −10 A has occurred as a gain error (an example of the measurement characteristic), and detects an intercept B of the straight line as an offset error (an example of the measurement characteristic).

Specifically, a straight line 60 indicated by a dotted line indicates a case where there is no occurrence of a gain error or an offset error in the current measurement circuit 35. When there is no occurrence of these errors in the current measurement circuit 35, the current value measured by the current measurement circuit 35 in response to detecting that a flow of the reference current value of +10 A has occurred indicates +10 A. Similarly, the current value measured by the current measurement circuit 35 in response to detecting that a flow the reference current value of −10 A has occurred indicates −10 A. Therefore, the slope A of the straight line 60 is 1, and the intercept B is 0.

A straight line 61 represents a case where there is occurrence of an offset error in the current measurement circuit 35. In the straight line 61, the current value measured by the current measurement circuit 35 in response to detecting that a flow of the reference current value of +10 A has occurred is +13 A, and the current value measured by the current measurement circuit 35 in response to detecting that a flow of the reference current value of −10 A has occurred is −7 A. Therefore, the slope A of the straight line 61 is 1, and the intercept B is 3. When there is occurrence of an offset error, the intercept B takes on a value other than 0, and the straight line is in a shape in which the straight line is shifted to the upper side or the lower side as compared to the case where there is no occurrence of an offset error.

A straight line 62 represents a case where there is occurrence of a gain error in the current measurement circuit 35. In the straight line 62, the current value measured by the current measurement circuit 35 in response to detecting that a flow of the reference current value of +10 A has occurred is +8 A, and the current value measured by the current measurement circuit 35 in response to detecting that a flow of the reference current value of −10 A has occurred is −8 A. Therefore, the slope A of the straight line 62 is 0.8, and the intercept B is 0. When there is occurrence of a gain error, the slope A takes on a value other than 1, and the straight line is in a shape in which the slope A is smaller than or greater than that of the case where there is no occurrence of a gain error.

In the present specification, the case where there is occurrence of only one of the offset error and the gain error has been exemplified. However, there may be a case where both of the offset error and the gain error occur.

The control unit 39 determines whether or not each of the detected slope A (gain error) and the detected intercept B (offset error) is within a normal range described below. The gain lower limit value, the gain upper limit value, the offset lower limit value, and the offset upper limit value described below are examples of the threshold values.
Gain lower limit value<Slope A<Gain upper limit value
Offset lower limit value<Intercept B<Offset upper limit value

The control unit 39 determines that the gain abnormality has occurred when the slope A is not within the normal range, and determines that the offset abnormality has occurred when the intercept B is not within the normal range. When it is determined that the gain abnormality or the offset abnormality has occurred, the control unit 39 notifies the vehicle ECU of the abnormality of the energy storage apparatus 1. If neither the gain abnormality nor the offset abnormality has occurred, the control unit 39 executes the correction formula setting processing for the current measurement circuit to be described next.

### (4-4) Correction Formula Setting Processing for Current Measurement Circuit

Even if no abnormality is detected in the current measurement circuit 35 by the abnormality detection processing for the current measurement circuit described above, the current value measured by the current measurement circuit 35 may include an offset error or a gain error within a normal range. The correction formula setting processing for the current measurement circuit is the processing of setting a correction formula for correcting the current value measured by the current measurement circuit 35 if no abnormality is detected in the current measurement circuit 35.

The correction formula is expressed by Equation 1 described below. In Equation 1, x represents a current value measured by the current measurement circuit 35, and y represents a corrected current value.

$$y = ( 1 / A ) x - B \qquad Equation 1$$

In the case of the straight line 61 illustrated in FIG. 6 mentioned above, since the slope A is 1 and the intercept B is 3, the correction formula is represented as Equation 2 described below.

$$y = x - 3 \qquad Equation 2$$

The corrected current value +10 A is derived when +13 A is substituted into Equation 2, and −10 A is derived when −7 A is substituted therein. In this way, the current value measured by the current measurement circuit 35 is corrected to a current value which is to be measured when there is no occurrence of a gain error or an offset error in the current measurement circuit 35 (that is, the current value which should be intrinsically measured).

In the case of the straight line 62 illustrated in FIG. 6, since the slope A is 0.8 and the intercept B is 0, the correction formula is represented as Equation 3 described below.

$$y = ( 1 / 0.8 ) x \qquad Equation 3$$

The corrected current value +10 A is derived when +8 A is substituted into Equation 3, and −10 A is derived when −8 A is substituted therein. In this way, the current value measured by the current measurement circuit 35 is corrected to a current value which is to be measured when there is no occurrence of a gain error or an offset error in the current measurement circuit 35 (that is, the current value which should be intrinsically measured).

### (5) Flow of Abnormality Detection Processing for Current Measurement Circuit and Correction Formula Setting Processing for Current Measurement Circuit

With reference to FIG. 7, a flow of the abnormality detection processing for the current measurement circuit and the correction formula setting processing for the current measurement circuit will be described. The present processing is started when the engine of the vehicle 2 is started. In other words, the present processing is started when a traveling operation of the vehicle 2 is started. The traveling operation of the vehicle 2 refers to a period from when the engine of the vehicle 2 is started to when the engine is stopped.

In S101, the control unit 39 determines whether or not the current detection circuit 36 has detected a flow of the reference current value of +10 A or the reference current value of −10 A. If a flow of either of the reference current values is detected to have occurred, the control unit 39 proceeds to S102, and if neither of the reference current values is detected, the control unit 39 repeats the processing of S101 until a flow of either of the reference current values is detected to have occurred.

In S102, the control unit 39 immediately measures the current value by the current measurement circuit 35. That is, when the current detection IC 36A detects that a flow of the reference current value has occurred, the control unit 39 immediately measures the current value by the current measurement circuit 35. The control unit 39 stores the measured current value in the RAM. In S103, the control unit 39 determines whether or not a flow of a reference current value different from the reference current value detected in S101 is detected to have occurred. For example, when a flow of the reference current value of +10 A is detected to have occurred in S101, it is determined in S103 whether or not a flow of the reference current value of −10 A is detected to have occurred. If a flow of a different reference current value is detected to have occurred, the control unit 39 proceeds to S104, and if no such a flow is detected, the control unit 39 repeats the processing of S103 until the flow is detected.

In S104, the control unit 39 measures a current value by the current measurement circuit 35 and stores the measured current value in the RAM.

In S105, the control unit 39 obtains the slope A (a gain error) and the intercept B (an offset error) of a straight line passing through the current value measured in S102 and the current value measured in S104.

In S106, the control unit 39 determines whether or not the slope A is within a normal range. If the slope A is not within the normal range, the control unit 39 proceeds to S107, and if the slope A is within the normal range, the control unit 39 proceeds to S108.

In S107, the control unit 39 determines that the gain abnormality has occurred.

In S108, the control unit 39 determines whether or not the intercept B is within a normal range. If the intercept B is not within the normal range, the control unit 39 proceeds to S109, and if the intercept B is within the normal range, the control unit 39 proceeds to S110.

In S109, the control unit 39 determines that the offset abnormality has occurred. In S110, the control unit 39 sets a correction formula mentioned above. After the correction formula has been set, a current value thereafter measured by the current measurement circuit 35 is corrected by using the set correction formula.

### (6) Effects of Embodiment

In the detection apparatus (the current detection circuit 36 and the control unit 39) according to Embodiment 1, when the measurement characteristic of the current measurement circuit 35 is to be detected, there is no need to switch the circuit by a selector switch so that no electric power is supplied to the auxiliary machines. Therefore, it is possible to detect the measurement characteristic of the current measurement circuit 35 while the auxiliary machines are being supplied with electric power. For this reason, the measurement characteristic can be detected even when the vehicle 2 is traveling (in other words, when the electric power supply to the auxiliary machines cannot be interrupted).

Depending on the vehicle 2, electric power must be supplied to the ECU, a security device, or the like, even during parking, and there may be a case where the electric power cannot be interrupted. In the detection apparatus according to Embodiment 1, the measurement characteristic of the current measurement circuit 35 can be detected while electric power is being supplied. Thus, the measurement characteristic can be detected even when the vehicle 2 is being parked and electric power to an electric load cannot be interrupted.

In the detection apparatus according to Embodiment 1, the measurement characteristic of the current measurement circuit 35 is detected by using the current detection circuit 36. Thus, there is also no need to provide a plurality of current measurement circuits as in the abnormality diagnosis apparatus for a current sensor described in JP2011-151986 A.

Therefore, according to the detection apparatus of Embodiment 1, it is possible to detect the measurement characteristic of the current measurement circuit 35 while the electric load is being supplied with electric power, and without providing another current measurement circuit.

The detection apparatus according to Embodiment 1 is particularly suitable for an apparatus conventionally including a current measurement circuit and a current detection circuit. For example, in some of energy storage apparatuses provided with an energy storage cell, such as a lithium-ion secondary battery, and a control unit which manages the energy storage cell, the energy storage apparatus conventionally includes a current measurement circuit and a current detection circuit. However, in such a conventional energy storage apparatus, the current detection circuit is not used for the detection of the measurement characteristic of the current measurement circuit, but is used for another purpose (for example, switching of the operation mode of the BMU). When the detection apparatus according to Embodiment 1 is applied to such an energy storage apparatus, a current detection circuit that is conventionally provided can be used for another application. Thus, it is possible to detect the measurement characteristic of the current measurement circuit without adding a new component.

According to the detection apparatus of Embodiment 1, a current value is measured by the current measurement circuit 35 immediately when a flow of a reference current value is detected to have occurred. Thus, a time difference between the time when the flow of the reference current value is detected to have occurred and the time when the current value is measured by the current measurement circuit 35 can be made as small as possible. Consequently, it is possible to detect the measurement characteristic of the current measurement circuit 35 more accurately than in the case where the time difference is large.

According to the detection apparatus of Embodiment 1, it is possible to detect an offset error of the current measurement circuit 35 while the electric load is being supplied with electric power, and without providing another current measurement circuit.

According to the detection apparatus of Embodiment 1, the line is a straight line (the straight lines 60 to 62). Since the straight line can be specified by two points on a coordinate system, the number of times the current value is measured for detecting the offset error can be reduced relative to a curved line.

According to the detection apparatus of Embodiment 1, it is possible to detect a gain error of the current measurement circuit 35 while the electric load is being supplied with electric power, and without providing another current measurement circuit.

According to the detection apparatus of Embodiment 1, the line is a straight line (the straight lines 60 to 62). Since the straight line can be specified by two points on a coordinate system, the number of times the current value is measured for detecting the gain error can be reduced relative to a curved line.

According to the detection apparatus of Embodiment 1, since the detected measurement characteristic is compared with a threshold value, it is possible to detect the presence or absence of abnormality in the current measurement circuit 35.

According to the detection apparatus of Embodiment 1, if no abnormality is detected in the current measurement circuit 35, a correction formula is set on the basis of the measurement characteristic. Therefore, by correcting the current value which has been measured by the current measurement circuit 35 by using the correction formula, it is possible to obtain a highly accurate current value even if a change occurs in the measurement characteristic of the current measurement circuit 35.

The reason why the correction formula is not set when an abnormality of the current measurement circuit 35 is detected is that there may be a case where continuously using the current measurement circuit 35 is not desirable if the abnormality is detected.

According to the detection apparatus of Embodiment 1, the detection accuracy of the current detection circuit 36 is equal to or higher than the measurement accuracy of the current measurement circuit 35. Thus, it is possible to detect the measurement characteristic of the current measurement circuit 35 more accurately than in the case where the detection accuracy of the current detection circuit 36 is less than the measurement accuracy of the current measurement circuit 35.

According to the energy storage apparatus 1 of Embodiment 1, it is possible to detect the measurement characteristic of the current measurement circuit 35 while maintaining electric power supply to the electric load, and without providing another current measurement circuit 35.

The energy storage apparatus 1 is mounted on the vehicle 2 having a load that needs to be supplied with electric power. The vehicle 2 having a load that needs to be supplied with electric power may be required to maintain the electric power supply to the electric load as much as possible. According to the energy storage apparatus 1, since the measurement characteristic of the current measurement circuit 35 can be detected while the electric load is being supplied with electric power, the energy storage apparatus 1 is suitable for the vehicle 2 having a load that needs to be supplied with electric power.

### Embodiment 2

The control unit 39 according to Embodiment 1 described above detects the measurement characteristic of the current measurement circuit 35 for each traveling operation of the vehicle 2 (i.e., from when the engine of the vehicle 2 is started to when the engine is stopped). In contrast, a control unit 39 of Embodiment 2 stores, for each traveling operation of a vehicle 2, a current value measured by a current measurement circuit 35 in response to detecting that a flow of a reference current value of +10 A has occurred, and a current value measured by the current measurement circuit 35 in response to detecting that a flow of a reference current value of −10 A has occurred in a storage unit 39B. The control unit 39 may store the current values in a RAM.

If the traveling operation is performed for a predetermined number of times or more (in other words, if the number of stored current values in the storage unit 39B reaches a predetermined number or more), in the subsequent traveling operation, when a flow of the reference current value of +10 A or the reference current value of −10 A is detected to have occurred, the control unit 39 compares the current value measured by the current measurement circuit 35 in response to detecting that the flow of the reference current value has occurred with a plurality of current values that are stored in the storage unit 39B. By performing this comparison, the control unit 39 determines whether there is a change in the measurement characteristic of the current measurement circuit 35. The control unit 39 detects the measurement characteristic when it is determined that the measurement characteristic has been changed.

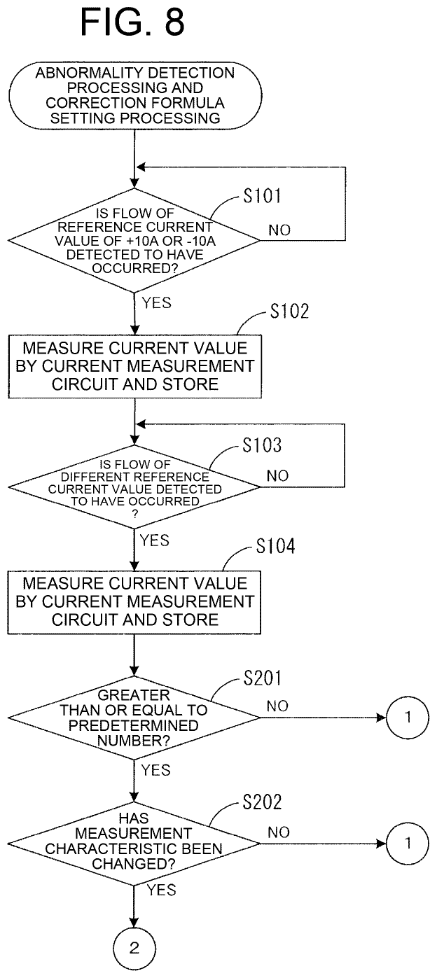

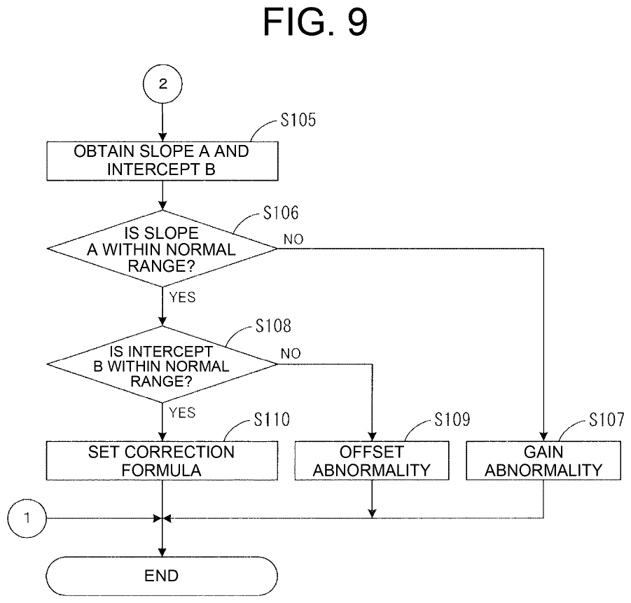

With reference to FIGS. 8 and 9, a flow of abnormality detection processing for the current measurement circuit and correction formula setting processing for the current measurement circuit according to Embodiment 2 will be described.

As indicated in FIG. 8, the control unit 39 according to Embodiment 2 executes S201 after S104. In S201, the control unit 39 determines whether or not the number of storage in the storage unit 39B of the current values measured in response to detecting that the flow of the reference current value of +10 A has occurred is greater than or equal to a predetermined number, and whether or not the number of storage in the storage unit 39B of the current values measured in response to detecting that the flow of the reference current value of −10 A has occurred is greater than or equal to the predetermined number. It is assumed that the above number of current values does not include the current value stored in S102 or S104 for the last time.

If the number of storage of the current values measured in response to detecting that the flow of the reference current value of +10 A has occurred and the number of storage of the current values measured in response to detecting that the flow of the reference current value of −10 A has occurred are both greater than or equal to the predetermined number, the control unit 39 proceeds to S202, and if not, the processing is ended.

In S202, the control unit 39 obtains a difference between the current value measured in S102 and a mean value of the current values (excluding the current value stored in S102 for the last time), among a plurality of current values that are stored in the storage unit 39B, measured in response to detecting that the flow of the same reference current value as that for which the flow is detected in S101 has occurred.

Similarly, the control unit 39 obtains a difference between the current value measured in S104 and a mean value of the current values (excluding the current value stored in S104 for the last time), among the plurality of current values that are stored in the storage unit 39B, measured in response to detecting that the flow of the same reference current value as that for which the flow is detected in S103 has occurred.

If both of the obtained differences are greater than or equal to threshold values, the control unit 39 determines that the measurement characteristic of the current measurement circuit 35 has been changed and proceeds to S105. If at least one of the differences is less than the threshold value, the control unit 39 determines that the measurement characteristic has not been changed and ends the processing.

If it is determined that the measurement characteristic has been changed, the control unit 39 deletes the current values stored in the storage unit 39B. This is because, unless these current values are deleted, it will be judged again that the number is greater than or equal to a predetermined number when S201 is executed next time, and the detection of the measurement characteristic is conducted.

In S202, the control unit 39 compares the difference between the current value measured in S102 or the current value measured in S104 and the mean value of the plurality of current values stored in the storage unit 39B with the threshold value. However, a difference from a median value of the plurality of current values may be compared with the threshold value.

According to a detection apparatus of Embodiment 2, a measurement characteristic is detected when it is determined that the measurement characteristic of the current measurement circuit 35 has been changed. Thus, it is possible to suppress excessive detection of the measurement characteristic as compared to the case of detecting the measurement characteristic for each traveling operation (in other words, each time when a flow is detected to have occurred for a plurality of reference current values).

### Embodiment 3

A control unit 39 according to Embodiment 3 detects, in addition to performing detection by a method of detecting the presence or absence of abnormality in a current measurement circuit 35 by using a current detection circuit 36 as in Embodiment 1 or 2, the presence or absence of abnormality in the current measurement circuit 35 by way of another method. The control unit 39 compares the detection results, thereby determining the presence or absence of abnormality in the current measurement circuit 35.

Specifically, the current measurement circuit 35 according to Embodiment 3 has a self-diagnostic function of self-diagnosing the presence or absence of abnormality in the current measurement circuit 35 itself. The self-diagnosis is performed by causing a current measurement IC 35B to transition to a diagnostic mode at the time of a sleep mode. In the self-diagnosis, a band gap is confirmed by causing the current measurement IC 35B to measure a current value obtained when a reference voltage is applied to a shunt resistor 35A, and it is determined whether or not the band gap is within an abnormal range. If the abnormal range is indicated, it means that the measured value greatly deviates from the actual value.

The control unit 39 according to Embodiment 3 detects the presence or absence of abnormality in the current measurement circuit 35 in the same manner as in Embodiment 1 or 2 described above. Further, in a case where a result of the detection indicates abnormality and a result of self-diagnosis of the current measurement circuit 35 also indicates abnormality, the control unit 39 determines that the current measurement circuit 35 is abnormal.

According to a detection apparatus of Embodiment 3, abnormality of the current measurement circuit 35 is detected by two methods, and if abnormality is indicated by both of the two methods, the current measurement circuit 35 is determined as being abnormal. Therefore, it is possible to reduce the possibility of erroneously judging that the current measurement circuit 35 is abnormal despite not being abnormal.

### OTHER EMBODIMENTS

The present invention is not limited to the embodiments explained with reference to the above description and the drawings, and the technical scope of the present invention also incorporates therein, for example, the following embodiments.
(1) In the above-described embodiment, the case of executing the abnormality detection processing for the current measurement circuit and the correction formula setting processing for the current measurement circuit has been exemplified. However, the correction formula setting processing for the current measurement circuit may not be executed. That is, the control unit 39 may only detect the presence or absence of abnormality in the current measurement circuit 35 on the basis of the detected measurement characteristic.
(2) In the above-described embodiment, the presence or absence of abnormality in the current measurement circuit 35 is detected on the basis of the detected measurement characteristic. However, the detection of the presence or absence of abnormality in the current measurement circuit 35 may not be performed. That is, it is sufficient if the control unit 39 only detects the measurement characteristic of the current measurement circuit 35.
(3) In the above-described embodiment, although the case where the first reference current value is +10 A and the second reference current value is −10 A has been exemplified, the first reference current value and the second reference current value can be decided as appropriate.
(4) In the above-described embodiment, although the case where the reference current values are +10 A and −10 A, i.e., the number of reference current values is two, has been exemplified, the number of reference current values to be employed may be three or more. When three or more reference current values are employed, an approximate straight line may be estimated by the least-squares method or the like from the three or more current values measured by the current measurement circuit 35 in response to detecting that the flow of each of the reference current values has occurred, and the measurement characteristic may be detected from that approximate straight line.
(5) In the above-described embodiment, although the case of detecting both of the offset error and the gain error has been exemplified, only one of the offset error and the gain error may be detected.
(6) In the above-described embodiment, although the straight lines 60 to 62 have been exemplified as the line, the line may be a curved line. When the line is a curved line, an approximate curve may be estimated by the least-squares method or the like from three or more current values measured by the current measurement circuit 35 in response to detecting that the flow of each of the reference current values has occurred.
(7) In the above-described embodiment, when a flow of the reference current value is detected to have occurred, the current value is immediately measured by the current measurement circuit 35. On the other hand, when a flow of the reference current value is detected to have occurred, the current value may be measured by slightly shifting the time. That is, there may be some time difference between the time when the flow of the reference current value is detected to have occurred and the time when the current value is to be measured by the current measurement circuit 35. However, it is preferable that the time difference should be made as small as possible.
(8) In the above-described embodiment, although the current measurement circuit 35 having the shunt resistor 35A has been exemplified, the current measurement circuit 35 is not limited thereto. For example, the current measurement circuit 35 may be a Hall sensor.
(9) In the above-described embodiment, although the current detection circuit 36 having the current detection IC 36A has been exemplified, the current detection circuit 36 is not limited thereto as long as the current detection circuit 36 can detect that a flow of the reference current value has occurred.
(10) In Embodiment 2 described above, although S201 and S202 are executed immediately after S104, S201 and S202 may be executed immediately after S102.
(11) In the above-described embodiment, although the energy storage apparatus 1 for starting an engine has been exemplified, the energy storage apparatus 1 may be used for an auxiliary machine which supplies electric power to auxiliary machines of an electric vehicle (EV).
(12) In the above-described embodiment, the case where the detection apparatus is applied to the energy storage apparatus 1 mounted on the vehicle 2 has been exemplified. However, the detection apparatus may be applied to an energy storage apparatus used for other purposes such as an energy storage apparatus mounted on a motorcycle, an industrial energy storage apparatus, and an energy storage apparatus which stores electric power generated by natural energy. In that case, applying the detection apparatus to an energy storage apparatus conventionally including a current measurement circuit and a current detection circuit is more suitable.
(13) In the above-described embodiment, although the case where the detection apparatus is applied to the energy storage apparatus has been exemplified, the detection apparatus may be applied to an apparatus other than the energy storage apparatus.
(14) In the above-described embodiment, although a secondary battery has been exemplified as the energy storage cell 30A, the energy storage cell 30A may be a capacitor involving an electrochemical reaction.
(15) In the above-described embodiment, although a lithium-ion secondary battery has been exemplified as the secondary battery, the secondary battery is not limited thereto. For example, the secondary battery may be a lead storage battery.

1. A detection apparatus which detects a measurement characteristic of a current measurement circuit which measures a current value of a current that flows through a circuit, the detection apparatus comprising:
a current detection circuit which detects, for a plurality of reference current values different from each other, a flow of the reference current value having occurred in the circuit; and
a control unit,
wherein the control unit measures, when the flow of the reference current value is detected to have occurred, a plurality of current values by the current measurement circuit, and detects the measurement characteristic of the current measurement circuit based on the plurality of reference current values and the plurality of current values measured by the current measurement circuit.

2. The detection apparatus according to claim 1, wherein
the control unit measures the current value by the current measurement circuit immediately when the flow of the reference current value is detected to have occurred.

3. The detection apparatus according to claim 1, wherein:
the measurement characteristic is an offset error; and
the control unit detects, in a coordinate system in which one axis represents the reference current value and the other axis represents the current value measured by the current measurement circuit, an intercept of a line passing through the current value measured by the current measurement circuit in response to detecting that a flow of a first reference current value, which is one of the plurality of reference current values, has occurred, and the current value measured by the current measurement circuit in response to detecting that a flow of a second reference current value, which is one of the plurality of reference current values, has occurred as the offset error.

4. The detection apparatus according to claim 3, wherein
the line is a straight line.

5. The detection apparatus according to claim 1, wherein:
the measurement characteristic is a gain error; and
the control unit detects, in a coordinate system in which one axis represents the reference current value and the other axis represents the current value measured by the current measurement circuit, a slope of a line passing through the current value measured by the current measurement circuit in response to detecting that a flow of a first reference current value, which is one of the plurality of reference current values, has occurred, and the current value measured by the current measurement circuit in response to detecting that a flow of a second reference current value, which is one of the plurality of reference current values, has occurred as the gain error.

6. The detection apparatus according to claim 5, wherein
the line is a straight line.

7. The detection apparatus according to claim 1, wherein
the control unit detects presence or absence of abnormality in the current measurement circuit by comparing the detected measurement characteristic with a threshold value.

8. The detection apparatus according to claim 7, wherein:
the current detection circuit has a function of self-diagnosing the presence or absence of abnormality in the current detection circuit itself; and
the control unit determines that the current measurement circuit is abnormal in a case where a result of comparing the detected measurement characteristic with the threshold value indicates abnormality and a result of self-diagnosis of the current measurement circuit also indicates abnormality.

9. The detection apparatus according to claim 7, wherein
if no abnormality is detected in the current measurement circuit, the control unit sets a correction formula for correcting the current value measured by the current measurement circuit based on the detected measurement characteristic.

10. The detection apparatus according to claim 1, wherein:
the detection apparatus is provided with a storage unit; and
the control unit stores, in the storage unit, the current value measured by the current measurement circuit in response to detecting that a flow of the reference current value has occurred, and if the number of stored current values reaches a predetermined number or more, the control unit compares a current value, which is thereafter measured by the current measurement circuit in response to detecting that a flow of the reference current value has occurred, with a plurality of current values stored in the storage unit, thereby determining whether the measurement characteristic of the current measurement circuit has been changed, and detects, when it is determined that the measurement characteristic has been changed, the measurement characteristic.

11. The detection apparatus according to claim 1, wherein
detection accuracy of the current detection circuit is equal to or higher than measurement accuracy of the current measurement circuit.

12. An energy storage apparatus comprising:
an energy storage cell;
a current measurement circuit which measures a current value of a current that flows through a circuit to which the energy storage cell is connected; and
the detection apparatus according to claim 1.

13. The energy storage apparatus according to claim 12, wherein
the energy storage apparatus is mounted on a vehicle having a load that needs to be supplied with electric power.

14. A detection method of detecting a measurement characteristic of a current measurement circuit which measures a current value of a current that flows through a circuit, the detection method comprising:
a step of detecting, for a plurality of reference current values different from each other, a flow of the reference current value having occurred in the circuit by a current detection circuit; and
a step of measuring, when the flow of the reference current value is detected to have occurred, a plurality of current values by the current measurement circuit, and detecting the measurement characteristic of the current measurement circuit based on the plurality of reference current values and the plurality of current values measured by the current measurement circuit.
